(19) United States
(12) Patent Application Publication
(10) Pub. No.: US 2025/0248122 A1
(43) Pub. Date: Jul. 31, 2025

(54) Display Apparatus

(71) Applicant: LG Display Co., Ltd., Seoul (KR)

(72) Inventors: Seonghwan Woo, Paju-si (KR); DongHun Jung, Paju-si (KR)

(21) Appl. No.: 18/781,071

(22) Filed: Jul. 23, 2024

(30) Foreign Application Priority Data
Jan. 30, 2024 (KR) 10-2024-0013717

(51) Int. Cl. H01L 27/12; H10K 59/126; H10K 59/127; H10K 59/131

(52) U.S. Cl. CPC H10D 86/60; H10D 86/441; H10K 59/126; H10K 59/1275; H10K 59/131; H10D 86/411

(57) ABSTRACT

A display apparatus may include a pad electrode on a substrate, a first line on the substrate and including a first metal layer and a second metal layer, an adhesive layer on the pad electrode, and a data driving circuit adjacent to the first line.

### CROSS REFERENCE TO RELATED APPLICATION

This application claims the benefit and priority to Republic of Korea Patent Application No. 10-2024-0013717, filed on Jan. 30, 2024, which is hereby incorporated by reference for all purposes.

### BACKGROUND

### Technical Field

Embodiments of the present disclosure relate to a display apparatus.

### Discussion of the Related Art

As the information society develops, there is increasing the demand for display apparatuses for displaying images in various forms. Therefore, in recent years, there have been used various display apparatuses such as liquid crystal display apparatuses and organic light emitting display apparatuses.

### SUMMARY

A display apparatus may include a display area and a non-display area. A chip or printed circuit board may be disposed in a non-display area of a display panel. There may be performed a bonding process to connect a chip or printed circuit board to the display panel.

When the bonding process proceeds, a crack may occur in the display panel. As cracks occur, moisture may penetrate into the display panel. In addition, voltage lines may be damaged.

Embodiments of the present disclosure may provide a display apparatus capable of preventing an occurrence of a crack in the display panel.

Embodiments of the present disclosure may provide a display apparatus capable of preventing or at least reducing a display panel from bending during a bonding process.

Embodiments of the present disclosure may provide a display apparatus capable of preventing or at least reducing a voltage line from being damaged.

Embodiments of the present disclosure may provide a display apparatus capable of reducing the resistance of a voltage supply line.

Embodiments of the present disclosure may provide a display apparatus capable of implementing low power consumption by reducing resistance.

A display apparatus according to embodiments of the present disclosure may include a substrate, a pad electrode on the substrate, a first line on the substrate and including a first metal layer and a second metal layer, an adhesive layer on the pad electrode, and a data driving circuit adjacent to the first line.

According to embodiments of the present disclosure, there may provide a display apparatus capable of preventing or at least reducing an occurrence of a crack in the display panel.

According to embodiments of the present disclosure, there may provide a display apparatus capable of preventing or at least reducing a display panel from bending during a bonding process.

According to embodiments of the present disclosure, there may provide a display apparatus capable of preventing or at least reducing a voltage line from being damaged.

According to embodiments of the present disclosure, there may provide a display apparatus capable of reducing the resistance of a voltage supply line.

According to embodiments of the present disclosure, there may provide a display apparatus capable of implementing low power consumption by reducing resistance.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure.

FIG. 1 is a system configuration diagram of a display apparatus according to embodiments of the present disclosure.

FIG. 2 illustrates a display panel according to embodiments of the present disclosure.

FIG. 3 is a cross-sectional view of a display area of a display panel according to embodiments of the present disclosure.

FIG. 4 is a plan view of a display apparatus according to embodiments of the present disclosure.

FIG. 5 illustrates an area A1 in FIG. 4 according to embodiments of the present disclosure.

FIG. 6 is a cross-sectional view along line I-I′ of FIG. 5 according to embodiments of the present disclosure.

FIGS. 7 to 9 illustrate an area A1 of FIG. 4 according to embodiments of the present disclosure.

FIGS. 10 and 11 illustrate an area A1 of FIG. 4 according to embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete, to assist those skilled in the art to understand the inventive concepts without limiting the protected scope of the present disclosure.

In describing elements of the present disclosure, the terms, “first,” “second,” “A,” “B,” “(a)” or “(b),” may be used. These terms are intended to identify the corresponding element(s) from the other element(s), and these are not used to define essence, order, sequence, or number of elements.

For the expression that an element (e.g., layer, film, region, component, section, or the like) “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

In describing a temporal relationship, when the temporal order is described as, for example, “after,” “subsequent to,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly)” is used.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Features of various embodiments of the present disclosure may be partially or overall coupled to or combined with each other, and may be variously inter-operated with each other and driven technically as those skilled in the art may sufficiently understand. The embodiments of the present disclosure may be carried out independently from each other, or may be carried out together in co-dependent relationship.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

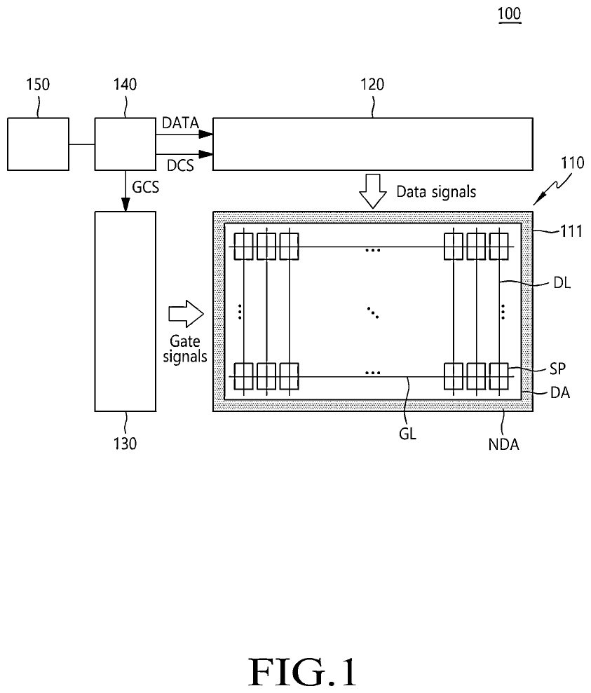

FIG. 1 is a system configuration diagram of a display apparatus 100 according to embodiments of the present disclosure.

Referring to FIG. 1, a display apparatus 100 according to embodiments of the present disclosure may include a display panel 110 and a display driving circuit as components configured to display an image. The display driving circuit is a circuit configured to drive the display panel 110, and may include a data driving circuit 120, a gate driving circuit 130, and a display controller 140.

The display panel 110 may include a substrate 111 and a plurality of subpixels SP that are disposed on the substrate 111.

The substrate 111 of the display panel 110 may include a display area DA configured to display an image and a non-display area NDA disposed at an outside of the display area DA.

A plurality of subpixels SP configured to display an image may be disposed in the display area DA, and the non-display area NDA may include a pad area disposed in a first direction from the display area DA.

In a display panel 110 according to embodiments of the present disclosure, the non-display area NDA may be smaller than the display area DA. In this disclosure, the non-display area NDA may be also referred to as a “bezel.”

For example, the non-display area NDA may include a first non-display area disposed outside the display area DA in a first direction, a second non-display area disposed outside the display area DA in a second direction intersecting the first direction, a third non-display area disposed outside the display area DA in the opposite direction to the first direction, and a fourth non-display area disposed outside the display area DA in the direction opposite to the second direction. One or two of the first to fourth non-display areas may include a pad area to which the data driving circuit 120 is connected or bonded (or attached). Among the first to fourth non-display areas, two or three which do not include the pad area may be very small in size, but embodiments of the present disclosure are not limited thereto.

In another example, a boundary area between the display area DA and the non-display area NDA may be bent so that the non-display area NDA may be disposed below the display area. In this case, when the user views at the display apparatus 100 from a front view, there may be little or no non-display area NDA visible to the user.

Various types of signal lines configured to drive a plurality of subpixels SP may be disposed on the substrate 111 of the display panel 110.

The display apparatus 100 according to embodiments of the present disclosure may be a liquid crystal display apparatus or the like, or may be a self-luminous display apparatus in which the display panel 110 emits light by itself. When the display apparatus 100 according to embodiments of the present disclosure is a self-luminous display apparatus, each of the plurality of subpixels SP may include a light emitting device.

For example, the display apparatus 100 according to embodiments of the present disclosure may be an organic light emitting display apparatus in which a light emitting device is implemented as an organic light emitting diode (OLED). For another example, the display apparatus 100 according to embodiments of the present disclosure may be an inorganic light emitting display apparatus in which the light emitting device is implemented as an inorganic-based light emitting diode. For another example, the display apparatus 100 according to embodiments of the present disclosure may be a quantum dot display apparatus in which a light emitting device is implemented with quantum dot which are semiconductor crystals emitting light by itself, or may be a micro LED display apparatus or a mini-LED display apparatus, however, embodiments of the present disclosure are not limited thereto.

The structure of each of the plurality of subpixels SP may vary based on the type of the display apparatus 100. For example, if the display apparatus 100 is a self-luminous display apparatus with the subpixel SP emitting light by itself, each subpixel SP may include a self-luminous light emitting device, one or more transistors, and one or more capacitors. However, embodiments of the present disclosure are not limited thereto.

For example, various types of signal lines may include a plurality of data lines DL configured to transmit (or transfer or supply) data signals (also called data voltages or image signals) and a plurality of gate lines GL configured to transmit (or transfer or supply) gate signals (also called scan signals).

For example, the plurality of data lines DL and the plurality of gate lines GL may cross each other. Each of the plurality of data lines DL may be arranged to extend in a first direction. Each of the plurality of gate lines GL may be arranged to extend in a second direction. Here, the first direction may be a column direction and the second direction may be a row direction. Alternatively, the first direction may be a row direction and the second direction may be a column direction. Hereinafter, for convenience of explanation, it will exemplified a case in which each of the plurality of data lines DL is arranged in a column direction, and each of the plurality of gate lines GL is arranged in a row direction.

The data driving circuit 120 is a circuit configured to drive a plurality of data lines DL, and may output data signals to the plurality of data lines DL.

The data driving circuit 120 may receive image data DATA in digital form from the display controller 140 and convert the received image data DATA into analog data signals to output to a plurality of data lines DL.

For example, the data driving circuit 120 may be connected to the display panel 110 by a tape automated bonding (TAB) method, or may be connected to a bonding pad of the display panel 110 using a chip-on-glass (COG) or chip-on-panel (COP) method, or may be implemented by a chip-on-film (COF) method and connected to the display panel 110.

The data driving circuit 120 may be connected to one side (e.g., the upper or lower side or one portion) of the display panel 110. Depending on the driving method, panel design method, etc., the data driving circuit 120 may be connected to both sides (e.g., upper and lower sides or both portions) of the display panel 110, or may be connected to two or more sides among the four sides of the display panel 110.

The data driving circuit 120 may be connected to the outside of the display area DA of the display panel 110, but alternatively, the data driving circuit 120 may be disposed at the display area DA of the display panel 110.

The gate driving circuit 130 is a circuit configured to drive a plurality of gate lines GL, and may output gate signals to the plurality of gate lines GL.

The gate driving circuit 130 may receive a first gate voltage corresponding to the turn-on level voltage and a second gate voltage corresponding to the turn-off level voltage along with various gate driving control signals GCS, and may generate gate signals and supply the generated gate signals to the plurality of gate lines GL.

In the display apparatus 100 according to embodiments of the present disclosure, the gate driving circuit 130 may be built into the display panel 110 as a gate-in-panel (GIP) type. If the gate driving circuit 130 is a gate-in-panel type, the gate driving circuit 130 may be formed on a substrate of the display panel 110 during the manufacturing process of the display panel 110.

In the display apparatus 100 according to embodiments of the present disclosure, the gate driving circuit 130 may be disposed in the display area DA of the display panel 110. For example, the gate driving circuit 130 may be disposed in a first partial area within the display area DA (e.g., a left area or a right area within the display area DA). For another example, the gate driving circuit 130 may be disposed in a first partial area within the display area DA (e.g., a left area or a right area within the display area DA) and a second partial area (e.g., a right area or a left area within the display area DA).

In the present disclosure, a gate driving circuit 130 built into the display panel 110 as a gate-in-panel type may be referred to as a “gate-in-panel circuit.”

The display controller 140 may be a device configured to control the data driving circuit 120 and the gate driving circuit 130, and may control the driving timing for the plurality of data lines DL and the driving timing of the plurality of gate lines GL.

The display controller 140 may supply a data driving control signal DCS to the data driving circuit 120 to control the data driving circuit 120, and may supply a gate driving control signal GCS to the gate driving circuit 130 to control the gate driving circuit 130.

The display controller 140 may receive input image data from a host system 150 and supply image data DATA to the data driving circuit 120 based on the input image data.

The display controller 140 may be implemented as a separate component from the data driving circuit 120, or may be integrated with the data driving circuit 120 and implemented as an integrated circuit.

The display controller 140 may be a timing controller used in a display technology, or may be a control device capable of further performing other control functions the function of a timing controller, or may be a control device different from the timing controller, or may be a control device other than a timing controller, or may be a circuit within the control device. The display controller 140 may be implemented with various circuits or electronic components, such as an integrated circuit (IC), a field programmable gate array (FPGA), an application specific integrated circuit (ASIC), or Processor. However, embodiments of the present disclosure are not limited thereto.

The display controller 140 may be mounted on a printed circuit board, a flexible printed circuit, etc., and may be electrically connected to the data driving circuit 120 and the gate driving circuit 130 through a printed circuit board, a flexible printed circuit.

The display controller 140 may transmit and receive signals to and from the data driving circuit 120 according to one or more predetermined interfaces. For example, the interface may include a low voltage differential signaling (LVDS) interface, an embedded clock point-point interface (EPI), or a serial peripheral interface (SPI). However, embodiments of the present disclosure are not limited thereto.

To provide not only an image display function but also a touch sensing function, the display apparatus 100 according to embodiments of the present disclosure may include a touch sensor and a touch sensing circuit configured to detect or sense an occurrence of a touch by a touch object such as a finger or pen or detect a touch position by sensing the touch sensor.

The touch sensing circuit may include a touch driving circuit configured to drive and sensing a touch sensor to generate and output touch sensing data, and a touch controller configured to detect or sense the occurrence of a touch or detect the touch position by a touch sensing data.

The touch sensor may include a plurality of touch electrodes. The touch sensor may further include a plurality of touch lines to electrically connect a plurality of touch electrodes and the touch driving circuit.

The touch sensor may exist outside the display panel 110 in the form of a touch panel or may exist inside the display panel 110. If the touch sensor exists outside the display panel 110 in the form of a touch panel, the touch sensor may be referred to as an external type. If the touch sensor is an external type, the touch panel and the display panel 110 may be manufactured separately and combined during the assembly process. The external touch panel may include a touch panel substrate and a plurality of touch electrodes on the touch panel substrate.

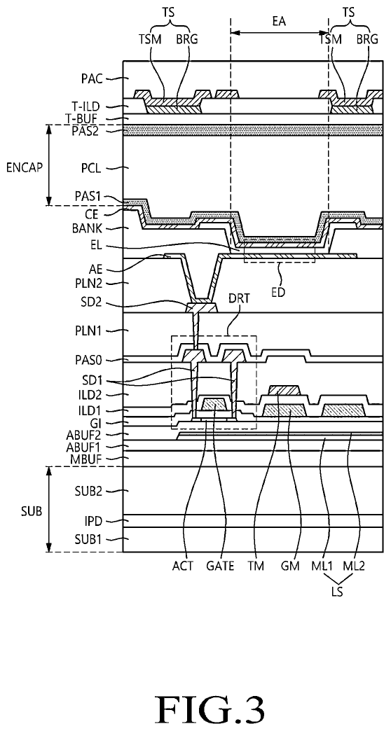

If the touch sensor exists inside the display panel 110, the touch sensor may be formed on the substrate SUB (see FIG. 3) along with signal lines and electrodes related to display driving during the manufacturing process of the display panel 110.

The touch driving circuit may supply a touch driving signal to at least one of the plurality of touch electrodes and generate touch sensing data by sensing at least one of the plurality of touch electrodes.

The touch sensing circuit may perform touch sensing by a self-capacitance sensing method or a mutual-capacitance sensing method.

If the touch sensing circuit performs touch sensing by a self-capacitance sensing method, the touch sensing circuit may perform touch sensing based on the capacitance between each touch electrode and a touch object (e.g., finger, pen, etc.). According to the self-capacitance sensing method, each of the plurality of touch electrodes may serve as a driving touch electrode and a sensing touch electrode. The touch driving circuit may drive all or part (or some portions) of the plurality of touch electrodes and sense all or part (or some portions) of the plurality of touch electrodes.

If the touch sensing circuit performs touch sensing by the mutual-capacitance sensing method, the touch sensing circuit may perform touch sensing based on the capacitance between touch electrodes. According to the mutual-capacitance sensing method, the plurality of touch electrodes may be divided into driving touch electrodes and sensing touch electrodes. The touch driving circuit may drive driving touch electrodes and sense sensing touch electrodes.

The touch driving circuit and the touch controller included in the touch sensing circuit may be implemented as separate devices or as one device (or integrated device). Additionally, the touch driving circuit and the data driving circuit may be implemented as separate devices or as one device (or integrated device).

The display apparatus 100 may further include a power supply circuit which supplies various types of power to the display driving circuit and/or the touch sensing circuit.

The display apparatus 100 according to embodiments of the present disclosure may be a mobile terminal such as a smart phone or tablet, or a monitor or television of various sizes, but is not limited thereto, and may be a display of various types and sizes capable of displaying information or images.

The display apparatus 100 according to embodiments of the present disclosure may further include an electronic apparatus such as a camera (e.g., image sensor) and a detecting sensor (or sensing sensor). For example, the detection sensor may be a sensor configured to detect an object or a human body by receiving light such as infrared, ultrasonic, or ultraviolet rays. However, embodiments of the present disclosure are not limited thereto.

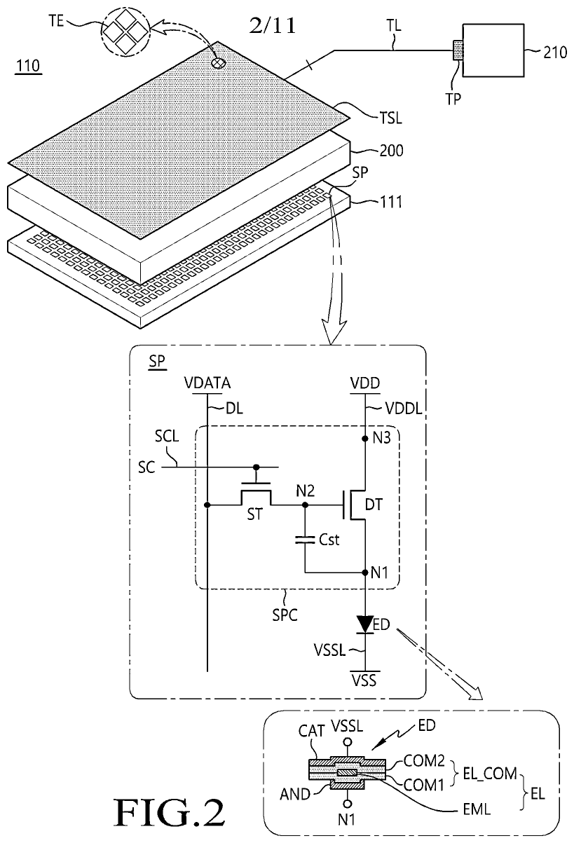

FIG. 2 illustrates a display panel 110 according to embodiments of the present disclosure.

Referring to FIG. 2, the display panel 110 may include a substrate 111 including a plurality of subpixels SP and an encapsulation layer 200 on the substrate 111. Here, the encapsulation layer 200 may also be referred to as an encapsulation substrate or an encapsulation part, but embodiments of the present disclosure are not limited thereto.

Referring to FIG. 2, when the display apparatus 100 according to embodiments of the present disclosure is a self-luminous display apparatus, each of the plurality of subpixels SP may include a light emitting device ED and a subpixel circuit SPC configured to drive the light emitting device ED. However, embodiments of the present disclosure are not limited thereto.

Referring to FIG. 2, the subpixel circuit SPC may include a plurality of pixel driving transistors and at least one capacitor configured to drive the light emitting device ED. In the present disclosure, the subpixel circuit SPC may drive the light emitting device ED by supplying a driving current to the light emitting device ED at a predetermined (or pre-defined) timing. The light emitting device ED may be driven by a driving current and emit light.

The plurality of pixel driving transistors may include a driving transistor DT configured to drive the light emitting device ED, and a scan transistor ST which is turned on or off based on the scan signal SC.

The driving transistor DT may supply a driving current to the light emitting device ED.

The scan transistor ST may be configured to control the electrical state of a corresponding node in the subpixel circuit SPC or to control the state or operation of the driving transistor DT.

At least one capacitor may include a storage capacitor Cst to maintain a constant voltage during a frame.

To drive the subpixel SP, a data signal VDATA which is an image signal, and a scan signal SC which is a gate signal may be applied to the subpixel SP. Further, a common pixel driving voltage including a first driving voltage VDD and a second driving voltage VSS may be applied to the subpixel SP to drive the subpixel SP.

The light emitting device ED may include an anode AND, a light emitting device layer EL, and a cathode CAT. The light emitting device layer EL may be disposed between the anode AND and the cathode CAT.

In the case that the light emitting device ED is an organic light emitting device, the light emitting device layer EL may include an emission layer EML, a first common layer COM1 between the anode AND and the emission layer EML, and a second common layer COM2 between the emission layer EML and the cathode CAT. The emission layer EML may be disposed in each subpixel SP. In comparison, the first common layer COM1 and the second common layer COM2 may be commonly disposed across a plurality of subpixels SP. The emission layer EML may be disposed in each emission area, and the first common layer COM1 and the second common layer COM2 may be commonly disposed across a plurality of emission areas and non-emission areas. The first common layer COM1 and the second common layer COM2 may be collectively referred to as a common layer EL_COM. However, embodiments of the present disclosure are not limited thereto.

For example, the first common layer COM1 may include a hole injection layer HIL and a hole transport layer HTL. The second common layer COM2 may include an electron transport layer ETL and an electron injection layer EIL. The hole injection layer may inject holes from the anode AND to the hole transport layer, the hole transport layer may transport holes to the emission layer EML, the electron injection layer may inject electrons from the cathode CAT to the electron transport layer, and the electron transport layer may transport electrons to the emission layer EML.

For example, the cathode CAT may be electrically connected to a second common driving voltage line VSSL. A second common driving voltage VSS, which is a type of common pixel driving voltage, may be applied to the cathode CAT through the second common driving voltage line VSSL. The anode AND may be electrically connected to a first node N1 of the driving transistor DT of each subpixel SP. In the present disclosure, the second common driving voltage VSS may also be referred to as a base voltage VSS, and the second common driving voltage line VSSL may also be referred to as a base voltage line VSSL, but embodiments of the present disclosure are not limited thereto.

For example, the anode AND may be a pixel electrode disposed in each subpixel SP, and the cathode CAT may be a common electrode commonly disposed in a plurality of subpixels SP. For another example, the cathode CAT may be a pixel electrode disposed in each subpixel SP, and the anode AND may be a common electrode commonly disposed in a plurality of subpixels SP. Hereinafter, for convenience of explanation, it is assumed that the anode AND is a pixel electrode and the cathode CAT is a common electrode.

Each light emitting device ED may be composed of overlapping parts of an anode AND, a light emitting device layer EL and a cathode CAT. A predetermined emission area may be formed by each light emitting device ED. For example, the emission area of each light emitting device ED may include an area where the anode AND, the light emitting device layer EL, and the cathode CAT overlap.

For example, the light emitting device ED may be an organic light emitting diode (OLED), an inorganic light emitting diode, or a quantum dot light emitting device. For example, in the case that the light emitting device ED is an organic light emitting diode OLED, the light emitting device layer EL in the light emitting device ED may include an organic light emitting device layer EL including an organic material.

The driving transistor DT may be a driving transistor configured to supply driving current to the light emitting device ED. The driving transistor DT may be connected between a first common driving voltage line VDDL and the light emitting device ED.

The driving transistor DT may include a first node N1, a second node N2, and a third node N3.

The first node N1 of the driving transistor DT may be electrically connected to the light emitting device ED, and the data signal VDATA may be applied to the second node N2. The driving voltage VDD from the first common driving voltage line VDDL may be supplied to the third node N3.

The second node N2 may be a gate node, the first node N1 may be a source node or a drain node, and the third node N3 may be a drain node or a source node, but embodiments of the present disclosure are not limited thereto. Hereinafter, for convenience of explanation, it will be described a case in which the second node N2 is a gate node, the first node N1 is a source node, and the third node N3 is a drain node in the driving transistor DT.

The scan transistor ST included in the subpixel circuit SPC illustrated in FIG. 2 may be a switching transistor configured to transmit (or transfer) a data signal VDATA, which is an image signal, to the second node N2 which is the gate node of the driving transistor DT.

The scan transistor ST may be controlled on-off by the scan signal SC which is a gate signal applied through the scan line SCL as a type of gate line GL, and may control the electrical connection between the second node N2 of the driving transistor DT and the data line DL. The drain electrode or source electrode of the scan transistor ST may be electrically connected to the data line DL, and the source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the second node N2 of the driving transistor DT. The storage capacitor Cst may be electrically connected to the first node N1 of the driving transistor DT. As another example, the storage capacitor Cst may include a first capacitor electrode and a second capacitor electrode. The first capacitor electrode may correspond to the first node N1 of the driving transistor DT. The second capacitor electrode may be electrically connected to the second node N2 of the driving transistor DT, or may correspond to the second node N2 of the driving transistor DT.

The storage capacitor Cst may be an external capacitor intentionally formed outside the driving transistor DT rather than a parasitic capacitor (e.g., Cgs, Cgd) as an internal capacitor which may exist between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

If the display panel 110 has a top emission structure, at least a portion of the subpixel circuit SPC may overlap with at least a portion of the light emitting device ED in the vertical direction. Alternatively, if the display panel 110 has a bottom emission structure, the subpixel circuit SPC may not overlap with the light emitting device ED in the vertical direction.

As shown in FIG. 2, the subpixel circuit SPC may have 2T-1C structure including two transistors DT and ST and one capacitor Cst. In some case, the subpixel circuit SPC may further include one or more transistors or one or more capacitors, but embodiments of the present disclosure are not limited thereto.

For example, the subpixel circuit SPC may have a 8T-1C structure including eight transistors and a single capacitor. For another example, the subpixel circuit SPC may have a 6T-2C structure including six transistors and two capacitors. For another example, the subpixel circuit SPC may have a 7T-1C structure including seven transistors and one capacitor. However, embodiments of the present disclosure are not limited thereto.

Depending on the structure of the subpixel circuit SPC, there may vary the type and number of gate signal and/or gate lines supplied to the subpixel SP.

Further, according to the structure of the subpixel circuit SPC, there may vary the type and number of common pixel driving voltages supplied to the subpixel SP.

Since circuit elements within each subpixel SP (in particular, light emitting devices EDs implemented with organic light emitting diodes (OLEDs) containing organic materials) are vulnerable to external moisture or oxygen, an encapsulation layer 200 may be disposed on the display panel 110 to prevent or at least reduce oxygen from penetrating into the circuit elements (particularly, the light emitting device ED). The encapsulation layer 200 may be configured in various shapes to prevent the light emitting device ED from coming into contact with moisture or oxygen.

Referring to FIG. 2, the display apparatus 100 according to embodiments of the present disclosure may include, to sense the user's touch, a touch sensor layer TSL including a plurality of sensor electrodes and a touch sensing circuit 210 configured to determine a presence or absence of a touch or touch coordinates by sensing a plurality of sensor electrodes.

The touch sensor layer TSL may be built into or embedded in the display panel 110. For example, the touch sensor layer TSL may be disposed on the encapsulation layer 200 within the display panel 110.

The display panel 110 may include, in addition to the touch sensor layer TSL, a plurality of touch pads to which the touch sensing circuit 210 is electrically connected, and a plurality of touch routing lines TL for electrically connecting a plurality of sensor electrodes included in the touch sensor layer TSL and a plurality of touch pads to which the touch sensing circuit 210 is connected.

FIG. 3 is a cross-sectional view of a display area of a display panel according to embodiments of the present disclosure.

Referring to FIG. 3, a substrate SUB may include a first substrate SUB1, an interlayer insulating film IPD, and a second substrate SUB2. The interlayer insulating film IPD may be located between the first substrate SUB1 and the second substrate SUB2. Since the substrate SUB is composed of the first substrate SUB1, the interlayer insulating film IPD and the second substrate SUB2, it is possible to prevent or at least reduce moisture penetration. For example, the first substrate SUB1 and the second substrate SUB2 may be polyimide (PI) substrates. The first substrate SUB1 may be referred to as a primary PI substrate, and the second substrate SUB2 may be referred to as a secondary PI substrate, but embodiments of the present disclosure are not limited thereto.

There may be disposed various patterns (e.g., ACT1, SD1, and GATE1) and various insulating films (e.g., MBUF, ABUF1, ABUF2, GI, ILD1, ILD2 and PAS0) and various metal patterns (e.g., TM, GM, ML1 and ML2) on the substrate SUB for configuring the transistor, for example, the driving transistor DRT or the like, but embodiments of the present disclosure are not limited thereto.

A buffer layer MBUF may be disposed on the second substrate SUB2, and a first buffer layer ABUF1 may be disposed on the buffer layer MBUF.

A first metal layer ML1 and a second metal layer ML2 may be disposed on the first buffer layer ABUF1. Here, the first metal layer ML1 and the second metal layer ML2 may be a light shield layer LS configured to shield light, but is not limited thereto.

A second buffer layer ABUF2 may be disposed on the first metal layer ML1 and the second metal layer ML2. An active layer ACT of the driving transistor DRT may be disposed on the second buffer layer ABUF2. The active layer ACT may be a semiconductor layer, but embodiments of the present disclosure are not limited thereto.

A first insulating film GI may be disposed on the active layer ACT. For example, a first insulating film GI may be disposed to cover the active layer ACT. The first insulating film GI may be a gate insulating film, but is not limited thereto.

A first gate electrode GATE1 of the driving transistor DRT may be disposed on the first gate insulating film GI. A gate material layer GM may be disposed on the first insulating film GI together with the first gate electrode GATE1 of the driving transistor DRT at a position different from the formation position of the driving transistor DRT.

A second insulating film ILD1 may be disposed to cover the first gate electrode GATE and the gate material layer GM. A metal pattern TM may be disposed on the second insulating film ILD1. The metal pattern TM may be disposed at a location different from the formation location of the driving transistor DRT. A third insulating film ILD2 may be disposed to cover the metal pattern TM on the second insulating film ILD1. The metal pattern TM may be a metal layer, but embodiments of the present disclosure are not limited thereto. The second insulating film ILD1 may be an interlayer insulating film, but is not limited thereto. The third insulating film ILD2 may be an interlayer insulating film, but is not limited thereto.

Two first source-drain electrodes SD1 may be disposed on the third insulating film ILD2. One of the two first source-drain electrodes SD1 may be a source node of the driving transistor DRT, and the other may be a drain node of the driving transistor DRT. The two first source-drain electrode SD1 may be electrically connected to one side (or one portion) and the other side (or the other portion) of the active layer ACT through a contact hole in the third insulating film ILD2, the second insulating film ILD1, and the first insulating film GI.

A portion of the active layer ACT which overlaps with the first gate electrode GATE1 may be a channel area. One of the two first source-drain electrodes SD1 may be connected to one side (or one portion) of the channel area in the active layer ACT, and the other one of the two first source-drain electrodes SD1 may be connected to the other side (or the other portion) of the channel area in the active layer ACT.

The passivation layer PAS0 may be disposed on the two first source-drain electrodes SD1. The passivation layer PAS0 may be disposed to cover the two first source-drain electrodes SD1. A planarization layer PLN1 and PNL2 may be disposed on the passivation layer PAS0. The planarization layer PLN1 and PNL2 may include a first planarization layer PLN1 and a second planarization layer PLN2, but is not limited thereto.

The first planarization layer PLN1 may be disposed on the passivation layer PAS0.

A second source-drain electrode SD2 may be disposed on the first planarization layer PLN1. The second source-drain electrode SD2 may be connected to one of the two first source-drain electrodes SD1 (which corresponds to the second node of the driving transistor DRT in the subpixel SP of FIG. 3) through a contact hole of the first planarization layer PLN1.

The second planarization layer PLN2 may be disposed on the second source-drain electrode SD2. The second planarization layer PLN2 may be disposed to cover the second source-drain electrode SD2. A light emitting device ED may be disposed on the second planarization layer PLN2.

The light emitting device ED may include an anode electrode AE, an light emission layer EL, and a cathode electrode CE, but is not limited to.

The anode electrode AE may be disposed on the second planarization layer PLN2. The anode electrode AE may be electrically connected to the second source-drain electrode SD2 through a contact hole in the second planarization layer PLN2.

A bank BANK may be disposed to cover a portion of the anode electrode AE. A portion of the bank BANK corresponding to the emission area EA of the subpixel SP may be open.

A part of the anode electrode AE may be exposed to an opening (i.e., open portion) of the bank BANK. An emission layer EL may be disposed on the side surface of the bank BANK and the opening (i.e., open portion) of the bank BANK. All or part (or some portions) of the emission layer EL may be disposed between adjacent banks BANK.

At the opening of the bank BANK, the emission layer EL may contact the anode electrode AE. A cathode electrode CE may be disposed on the emission layer EL.

A light emitting device ED may be formed by an anode electrode AE, an emission layer EL and a cathode electrode CE. The emission layer EL may include an organic layer, but is not limited thereto.

An encapsulation layer ENCAP may be disposed on the light emitting device ED.

The encapsulation layer ENCAP may have a single-layer structure or a multi-layer structure. For example, as shown in FIG. 3, the encapsulation layer ENCAP may include a first inorganic encapsulation layer PAS1, an organic encapsulation layer PCL, and a second inorganic encapsulation layer PAS2, but is not limited thereto.

For example, the first inorganic encapsulation layer PAS1 and the second inorganic encapsulation layer PAS2 may be inorganic films, and the organic encapsulation layer PCL may be an organic film, but is not limited thereto. Among the first inorganic encapsulation layer PAS1, the organic encapsulation layer PCL, and the second inorganic encapsulation layer PAS2, the organic encapsulation layer PCL may be a planarization layer, but is not limited thereto.

The first inorganic encapsulation layer PAS1 may be disposed on the cathode electrode CE, and may be disposed closest to the light emitting device ED. The first inorganic encapsulation layer PAS1 may be formed of an inorganic insulating material capable of low-temperature deposition. For example, the first inorganic encapsulation layer PAS1 may be silicon nitride (SiNx), silicon oxide (SiOx), silicon oxynitride (SiONx), or aluminum oxide (Al₂O₃), but is not limited thereto. For example, since the first inorganic encapsulation layer PAS1 is deposited in a low-temperature atmosphere, the first inorganic encapsulation layer PAS1 may prevent the emission layer EL containing organic materials vulnerable to high-temperature atmospheres from being damaged during the deposition process.

The organic encapsulation layer PCL may be formed to have a smaller area than the first inorganic encapsulation layer PAS1. The organic encapsulation layer PCL may be formed to expose both ends of the first inorganic encapsulation layer PAS1. The organic encapsulation layer PCL may serve as a buffer to relieve stress between each layer due to bending of the display apparatus 100, and may also serve to enhance planarization performance. For example, the organic encapsulation layer PCL may be acrylic resin, epoxy resin, polyimide, polyethylene, or silicon oxycarbon (SiOC), and may be formed of an organic insulating material, but is not limited thereto. For example, the organic encapsulation layer PCL may be formed by an inkjet method, but is not limited thereto.

The second inorganic encapsulation layer PAS2 may be formed to cover an upper surface and a side surface of each of the organic encapsulation layer PCL and the first inorganic encapsulation layer PAS1 on the substrate SUB on which the organic encapsulation layer PCL is formed. The second inorganic encapsulation layer PAS2 may minimize or block external moisture or oxygen from penetrating into the first inorganic encapsulation layer PAS1 and the organic encapsulation layer PCL. For example, the second inorganic encapsulation layer PAS2 may be formed of an inorganic insulating material such as silicon nitride (SiNx), silicon oxide (SiOx), silicon oxynitride (SiON), or aluminum oxide (Al₂O₃), but is not limited thereto.

Referring to FIG. 3, when a touch part TS is a type built into the display panel 110, the touch part TS may be disposed on the encapsulation layer ENCAP.

A buffer film T-BUF may be disposed on the encapsulation layer ENCAP. The touch part TS may be disposed on the buffer film T-BUF. The buffer film T-BUF may be a touch buffer film, but is not limited thereto.

The touch part TS may include touch metals TSM and bridge metal BRG. The touch metals TSM and bridge metals BRG may be disposed on different layers, but are not limited thereto.

A insulating film T-ILD may be disposed between the touch metals TSM and the bridge metal BRG.

For example, the touch metals TSM may include a first touch metal TSM, a second touch metal TSM, and a third touch metal TSM arranged adjacent to each other, but embodiments of the present disclosure are not limited thereto. In the case that the third touch metal TSM is disposed between the first touch metal TSM and the second touch metal TSM, and the first touch metal TSM and the second touch metal TSM are required to be electrically connected to each other, the first touch metal TSM and the second touch metal TSM may be electrically connected to each other through a bridge metal BRG located on a different layer. The bridge metal BRG may be insulated from the third touch metal TSM by a insulating film T-ILD.

When the touch part TS is formed on the display panel 110, there may be generated the chemical solutions (developer or etchant, etc.) used in the process or the moisture from the outside. By disposing the touch part TS on the buffer film T-BUF, chemical solutions or moisture may be prevented from penetrating into the emission layer EL including organic materials during the manufacturing process of the touch part TS. Accordingly, the buffer film T-BUF may prevent damage to the emission layer EL which is vulnerable to chemicals or moisture.

The buffer film T-BUF may be formed at a low temperature below a specific temperature (e.g., 100 degrees Celsius) to prevent or at least reduce damage to the emission layer EL including organic materials vulnerable to high temperatures, and may be formed of an organic insulating material with a low dielectric constant of 1˜3, but embodiments of the present disclosure are not limited thereto. For example, the buffer film T-BUF may be formed of an acrylic-based material, epoxy-based material, or siloxane-based material, but embodiments of the present disclosure are not limited thereto. As the display apparatus 100 is bent, the encapsulation layer ENCAP may be damaged and the touch metal TSM disposed on the buffer film T-BUF may be broken. But even if the display apparatus 100 is bent, the buffer film T-BUF, which is formed of an organic insulating material and has a flattening performance, may prevent damage to the encapsulation layer ENCAP and/or cracking of the metals (e.g., TSM, BRG) constituting the touch part TS.

The protection layer PAC may be disposed on the touch part TS. For example, the protection layer PAC may be disposed to cover the touch sensor TS. The protection layer PAC may be an organic insulating film, but is not limited thereto.

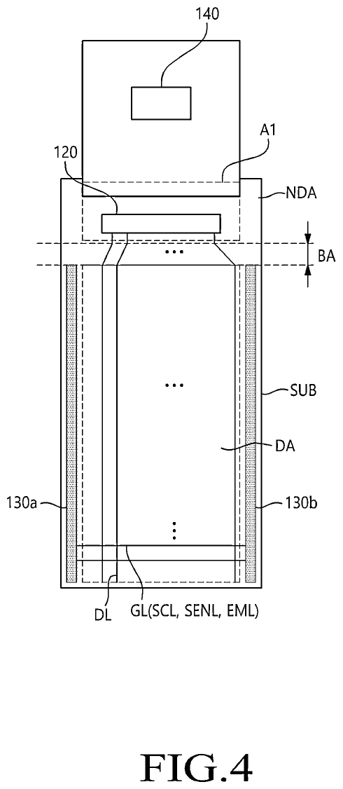

FIG. 4 is a plan view of a display apparatus 100 according to embodiments of the present disclosure.

Referring to FIG. 4, the substrate SUB may include a display area DA and a non-display area NDA.

The data driving circuit 120 and the gate driving circuits 130a and 130b may be disposed at the non-display area NDA.

The data driving circuit 120 may be disposed in a chip-on-panel scheme on the substrate SUB. The data driving circuit 120 may be electrically connected to the display panel 110 through the data line DL.

The gate driving circuits 130a and 130b may be disposed on the substrate SUB. The gate driving circuits 130a and 130b may be in the form of a GIP disposed inside the display panel. The gate driving circuits 130a and 130b may be disposed at left and right ends of the display area DA on the substrate SUB, but embodiments of the present disclosure are not limited thereto.

The gate driving circuits 130a and 130b may be electrically connected to subpixels disposed at the display area DA through the gate line GL. The plurality of gate lines GL may be arranged to intersect the plurality of data lines DL, but embodiments of the present disclosure are not limited thereto.

The plurality of gate lines GL may be a scan signal line SCL, a sense signal line SENL, and an emission control line EML.

When the gate line GL is the scan signal line SCL, the scan signal line SCL may be electrically connected to a gate node of the scan transistor ST shown in FIG. 2.

When the gate line GL is the sense signal line SENL, the sense signal line SENL may be electrically connected to the gate node of the sensing transistor. The sensing transistor may be included in the subpixel SP shown in FIG. 2, and the sensing transistor may be electrically connected to the first node N1.

When the gate line GL is the emission control line EML, the emission control line EML may be electrically connected to the gate node of an emission control transistor. When the subpixel SP is configured as 7T1C or 8T1C, the emission control transistor may be included in the subpixel SP.

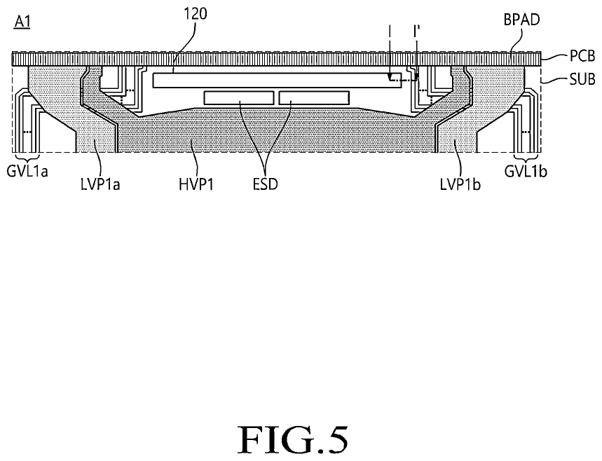

The display controller 140 may be disposed on a printed circuit board PCB (see FIG. 5). The display controller 140 may control the data driving circuit 120 and the gate driving circuits 130a and 130b. The printed circuit board PCB may be coupled to an upper part of the substrate SUB.

The substrate SUB may include a bending area BA capable of being bent. The bending area BA may be an area between the data driving circuit 120 and the display area DA.

FIG. 5 illustrates a first area A1 in FIG. 4 according to embodiments of the present disclosure. FIG. 5 is a plan view in which the data driving circuit 120 and the substrate SUB are combined according to embodiments of the present disclosure. FIG. 5 is a plan view of the data driving circuit 120 and the substrate SUB according to embodiments of the present disclosure being combined in a chip-on-film scheme.

Referring to FIG. 5, the substrate SUB, the data driving circuit 120, and a printed circuit board PCB may be disposed in a first area A1.

The substrate SUB may include a pad BPAD. The printed circuit board PCB may be combined with a substrate SUB at the pad BPAD. The pad BPAD may be a bonding pad or a connection pad, but embodiments of the present disclosure are not limited thereto.

The pad BPAD may be electrically connected to a plurality of gate voltage lines GVL1a and GVL1b, and plates HVP1, LVP1a and LVP1b. The plates HVP1, LVP1a and LVP1b may include a first line HVP1 and a second line LVP1a or LVP1b. The pad BPAD may include a first area disposed at an outermost portion of the pad BPAD, a second area disposed adjacent to the first area, and a third area electrically connected to the first line HVP1.

The second lines LVP1 may be disposed at the leftmost and rightmost portions of the pad BPAD. A second line LVP1a of the left side may be disposed at the leftmost portion of the pad BPAD. A second line LVP1b of the right side may be disposed at the rightmost portion of the pad BPAD.

The second lines LVP1 may be lines configured to supply voltage. The second lines LVP1 may be a wide plate-shaped lines, but embodiments of the present disclosure are not limited thereto. The second lines LVP1 may be lines supplied with a base voltage. For example, the second line LVP1 may be a line which is supplied with a different voltage than the first line HVP1, but is not limited thereto. For example, the second line LVP1 may be a line which is supplied with a low voltage, but is not limited thereto. For example, the second line LVP1 may be a line supplied with a low-potential driving voltage VSS, but is not limited thereto.

The first line HVP1 may be disposed in contact with at least one or more of the pads BPAD, but embodiments of the present disclosure are not limited thereto. Referring to FIG. 5, the first line HVP1 may have a “U” shape, but embodiments of the present disclosure are not limited thereto. The first line HVP1 may include a left portion connected to the pad BPAD of left side and a right portion connected to the pad BPAD of right side.

The first line HVP1 may be a line to which a voltage is supplied. The first line HVP1 may be a wide plate-shaped line or a single line, but embodiments of the present disclosure are not limited thereto. The first line HVP1 may be a line supplied with a driving voltage. The first line HVP1 may be a line supplied with a high voltage, but is not limited thereto. For example, the first line HVP1 may be a line supplied with a high-potential driving voltage VDD, but is not limited thereto.

With respect to a horizontal direction, the first line HVP1 may be disposed inside the second line LVP1. The left portion of the first line HVP1 may be disposed to the right side than the left second line LVP1a. The right portion of the first line HVP1 may be disposed to the left side than the right second line LVP1b.

The gate voltage lines GVL1a and GVL1b may be disposed inside than the first line HVP1. The gate voltage lines GVL1a and GVL1b may be supplied with a clock signal or a start signal, but embodiments of the present disclosure are not limited thereto. The second line LVP1 may be electrically connected to the pad BPAD in the first area, and the gate voltage lines GVL1a and GVL1b may be electrically connected to the pad BPAD in the second area.

The gate voltage lines GVL1a and GVL1b may be disposed between the first lines HVP1 and the data driving circuit 120.

The gate voltage line GVL1a disposed at the left side may be arranged to extend downward from the pad BPAD, and then bent to the left side. The gate voltage line GVL1a arranged at the left side may be arranged to bend to the left side, and then extend downward again. The gate voltage lines GVL1a at the left side may be disposed at the leftmost side of the first area A1.

The second line LVP1a disposed at the left side may be disposed at the right side of the gate voltage lines GVL1a disposed at the left side, but is not limited thereto.

The gate voltage lines GVL1b disposed at the right side may be arranged to extend downward from the pad BPAD, and then bent to the right side. The gate voltage lines GVL1b disposed at the right side may be arranged to bend to the right side, and then extend downward again. The gate voltage lines GVL1b disposed at the right side may be disposed at the rightmost side of the first area A1.

The second line LVP1b disposed at the right side may be disposed at the left side of the gate voltage line GVL1b disposed at the right side.

A lower part of the first line HVP1 may be disposed between the second lines LVP1a and LVPb.

The data driving circuit 120 may be disposed between the gate voltage line GVL1a disposed at the left side and the gate voltage line GVL1b arranged at the right side.

The data driving circuit 120 may have a rectangular shape elongated in left and right directions, but embodiments of the present disclosure are not limited thereto.

An electrostatic discharge circuit ESD may be disposed between a lower part of the first line HVP1 and the data driving circuit 120. The electrostatic discharge circuit ESD may prevent overcurrent from flowing due to static electricity.

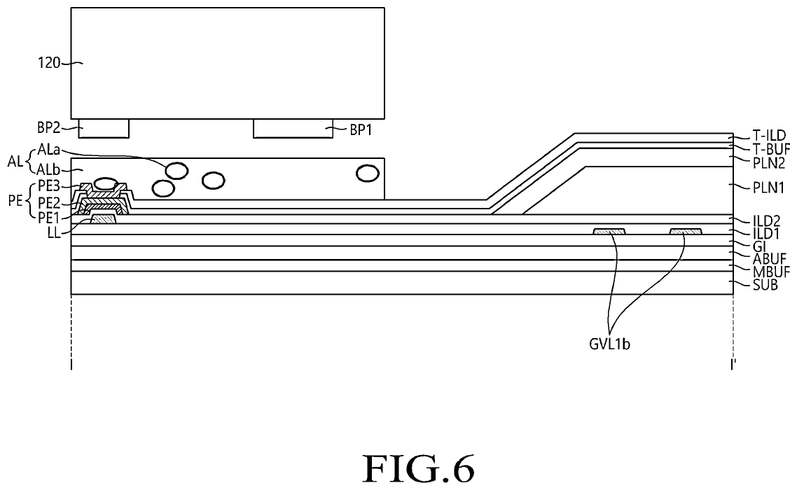

The data driving circuit 120 may be electrically connected to a plurality of link lines LL (see FIG. 6). The data driving circuit 120 may be electrically connected to subpixels through a plurality of link lines LL.

FIG. 6 is a cross-sectional view along line I-I′ of FIG. 5 according to embodiments of the present disclosure.

Referring to FIG. 6, the data driving circuit 120 may be electrically connected to pad electrodes PE disposed at the substrate SUB.

Referring to FIG. 6, a portion of the gate voltage line GVL1b may be disposed on a first insulating film GI. The substrate SUB and the buffer layer MBUF and ABUF may be disposed under the first insulating film GI. Since the configurations of the substrate SUB and buffer layers MBUF and ABUF shown in FIG. 6 may be substantially the same as those of the substrate SUB and buffer layers MBUF and ABUF shown in FIG. 3, there will be omitted or simplified the repetitive descriptions.

The second insulating film ILD1 may be disposed on a portion of the gate voltage line GVL1b and the first insulating film GI. For example, the second insulating film ILD1 may be disposed to cover a portion of the gate voltage line GVL1b and the first insulating film GI.

The third insulating film ILD2 may be disposed on the second insulating film ILD1. For example, the third insulating film ILD2 may be disposed to cover the second insulating film ILD1.

The first planarization layer PLN1 may be disposed on the third insulating film ILD2. The first planarization layer PLN1 may be disposed to overlap a portion of the gate voltage line GVL1b. The first planarization layer PLN1 shown in FIG. 6 may be formed at the same time as the first planarization layer PLN1 shown in FIG. 3, but embodiments of the present disclosure are not limited thereto. The first planarization layer PLN1 shown in FIG. 6 may be integrated with the first planarization layer PLN1 shown in FIG. 3, or may be disposed to be spaced apart from the first planarization layer PLN1 shown in FIG. 3.

The second planarization layer PLN2 may be disposed on the first planarization layer PLN1. For example, the second planarization layer PLN2 may be disposed to cover the first planarization layer PLN1. Referring to FIG. 6, the left portion of the first planarization layer PLN1 may have an inclined shape (or a slanted shape), but embodiments of the present disclosure are not limited thereto. Accordingly, the left portion of the second planarization layer PLN2 may also have an inclined shape (or a slanted shape).

The buffer film T-BUF may be disposed on the second planarization layer PLN2. For example, the buffer film T-BUF may be disposed to cover the second planarization layer PLN2. The buffer film T-BUF shown in FIG. 6 may be formed integrally with the buffer film T-BUF shown in FIG. 3, but embodiments of the present disclosure are not limited thereto.

The insulating film T-ILD may be disposed on the buffer film T-BUF. For example, the insulating film T-ILD may be disposed to cover the buffer film T-BUF. The insulating film T-ILD shown in FIG. 6 may be formed integrally with the insulating film T-ILD shown in FIG. 3, but embodiments of the present disclosure are not limited thereto.

A link line LL may be disposed on the second insulating film ILD1. The link line LL may be a line for transmitting signals. For example, the link line LL may be a data line or a reference voltage line, but embodiments of the present disclosure are not limited thereto. The link line LL shown in FIG. 6 may include a material included in the gate material layer GM shown in FIG. 3, but embodiments of the present disclosure are not limited thereto. The link line LL shown in FIG. 6 may be formed together with the gate material layer GM shown in FIG. 3, but embodiments of the present disclosure are not limited thereto.

The third insulating film ILD2 may be disposed on the link line LL and the second insulating film ILD1. For example, the third insulating film ILD2 may be disposed to cover the link line LL and the second insulating film ILD1.

A pad electrode PE may be disposed on the link line LL to be spaced apart from the link line LL. The pad electrode PE may include a first pad electrode PE1, a second pad electrode PE2, and a third pad electrode PE3 in one embodiment.

The first pad electrode PE1 may be disposed on the third insulating film ILD2. The first pad electrode PE1 may be disposed to overlap the link line LL, but embodiments of the present disclosure are not limited thereto. The first pad electrode PE1 shown in FIG. 6 may include a same material as the first source-drain electrode SD1 shown in FIG. 3, but embodiments of the present disclosure are not limited thereto. The first pad electrode PE1 shown in FIG. 6 may be formed together with the first source-drain electrode SD1 shown in FIG. 3, but embodiments of the present disclosure are not limited thereto.

The second pad electrode PE2 may be disposed on the first pad electrode PE1. The second pad electrode PE2 may be disposed to cover the first pad electrode PE1. The second pad electrode PE2 may be disposed to overlap the link line LL. The second pad electrode PE2 shown in FIG. 6 may include a same material as the second source-drain electrode SD2 shown in FIG. 3, but embodiments of the present disclosure are not limited thereto. The second pad electrode PE2 shown in FIG. 6 may be formed together with the second source-drain electrode SD2 shown in FIG. 3, but embodiments of the present disclosure are not limited thereto.

A buffer film T-BUF may be disposed on the second pad electrode PE2 and the third insulating film ILD2. For example, the buffer film T-BUF may be disposed to cover the second pad electrode PE2 and the third insulating film ILD2.

An insulating film T-ILD may be disposed on the buffer film T-BUF. For example, the insulating film T-ILD may be disposed to cover the buffer film T-BUF.

In an area overlapping with the second pad electrode PE2, a part of the buffer film T-BUF and a part of the insulating film T-ILD may be etched and removed.

The third pad electrode PE3 may be electrically connected to the second pad electrode PE2 through a portion of the buffer film T-BUF that has been etched and removed. In an area overlapping with the second pad electrode PE2, the third pad electrode PE3 may be disposed in contact with a portion of the buffer film T-BUF and a portion of the insulating film T-ILD. In an area overlapping with the second pad electrode PE2, the third pad electrode PE3 may be disposed in contact with the second pad electrode PE2. The third pad electrode PE3 may be formed together with the touch metals TSM and/or the bridge metal BRG, but embodiments of the present disclosure are not limited thereto.

An adhesive layer AL may be disposed between the pad electrode PE and the data driving circuit 120. The adhesive layer AL may include a conductive ball ALa and an adhesive ALb. The adhesive layer AL may be an anisotropic conductive film, but embodiments of the present disclosure are not limited thereto.

The conductive ball ALa of the adhesive layer AL may have a spherical shape, but embodiments of the present disclosure are not limited thereto. The conductive ball ALa may have conductive property. The conductive ball ALa may have a core and a shell structure surrounding the core. The core may include resin, etc., but embodiments of the present disclosure are not limited thereto. The shell may be formed of any one or alloy of gold (Au), silver (Ag), nickel (Ni), copper (Cu), lead (Pb), and platinum (Pt), but embodiments of the present disclosure are limited thereto.

The adhesive ALb of the adhesive layer AL may include a resin-based material having adhesive properties, but embodiments of the present disclosure are not limited thereto. The adhesive ALb of the adhesive layer AL may fix the conductive ball ALa inside the adhesive ALb. The adhesive ALb of the adhesive layer AL may connect or couple the substrate SUB and the data driving circuit 120.

Referring to FIG. 6, the data driving circuit 120 may include a first bump BP1 and a second bump BP2. The data driving circuit 120 may include a plurality of bumps. However, for convenience of explanation, only the first bump BP1 and the second bump BP2 are shown, but embodiments of the present disclosure are not limited thereto.

The first bump BP1 may be a bump configured to fix the position at which the data driving circuit 120 is coupled to the substrate SUB. The first bump BP1 may be an alignment bump, but is not limited thereto. The first bump BP1 may be disposed to overlap the first line.

The second bump BP2 may be a bump configured to transmit (or transfer) signal. The second bump BP2 may be electrically connected to the pad electrode PE, and the second bump BP2 may supply a signal to the pad electrode PE.

The data driving circuit 120 may be connected or coupled to the substrate SUB by a bonding (or attaching) process.

The adhesive ALb of the adhesive layer AL may bond (or attach) the data driving circuit 120 and the substrate SUB so that they are not separated or detached.

The conductive ball ALa of the adhesive layer AL may be disposed between the second bump BP2 and the pad electrode PE. The conductive ball Ala may be able to facilitate signal transmission between the data driving circuit 120 and the pad electrode PE.

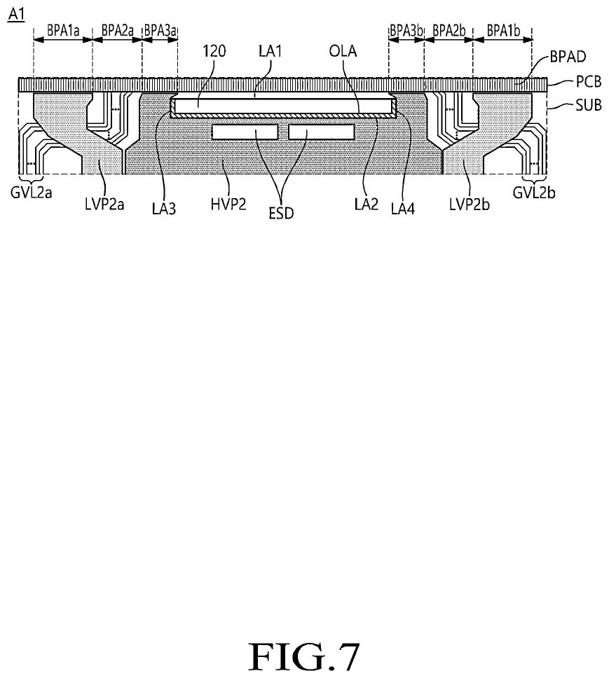

FIGS. 7 to 9 illustrate area A1 of FIG. 4 according to another embodiment of the present disclosure. FIGS. 7, 8, and 9 are plan views in which the data driving circuit 120 and the substrate SUB are coupled according to embodiments of the present disclosure. FIGS. 7 to 9 illustrate the data driving circuit 120 and the substrate SUB being coupled in a chip-on-film scheme.

In describing FIGS. 7 to 9, terms such as up and down, left and right, top and bottom, and sides may be used. Descriptions of up and down, left and right, top and bottom, and sides are based on the plan views of FIGS. 7 to 9.

Referring to FIGS. 7 to 9, the substrate SUB, the data driving circuit 120, and a printed circuit board PCB may be disposed at a first area A1.

Referring to FIG. 7, the area where a pad BPAD is disposed may include a first area BPA1a and BPA1b, a second area BPA2a and BPA2b, and a third area BPA3a and BPA3b.

The first areas BPA1a and BPA1b may be areas at the left and right ends of the pad BPAD.

The second areas BPA2a and BPA2b may be an area disposed inside the pad BPAD than the first areas BPA1a and BPA1b. The second areas BPA2a and BPA2b may be disposed adjacent to the first areas BPA1a and BPA1b.

The third areas BPA3a and BPA3b may be an area disposed inside the pad BPAD than the second areas BPA2a and BPA2b. The third areas BPA3a and BPA3b may be disposed adjacent to the second areas BPA2a and BPA2b.

The first area BPA1a and BPA1b may be the area closest to the end of the pad BPAD, and the third area BPA3a and BPA3b may be the area furthest from the end of the pad BPAD.

The second lines LVP2a and LVP2b may be electrically connected to the pad BPAD of the first area BPA1a and BPA1b. The second line LVP2a and LVP2b may be a wide plate-shaped line, but embodiments of the present disclosure are not limited thereto.

Referring to FIG. 7, the second line LVP2a of the left side may be electrically connected to the pad BPAD in the first area BPA1a of the left side. The second line LVP2b of the right side may be electrically connected to the pad BPAD of the first area BPA1b of the right side.

Referring to FIG. 7, the second line LVP2a on the left side may be in a form of a curved line. The second line LVP2a of the left side may be arranged so that its middle portion is bent to the right side. The second line LVP2a of the left side may include an area overlapping with the gate voltage line GVL2a of the left side.

Referring to FIG. 7, the second line LVP2b of the right side may be in the form of a curved line. The second line LVP2b of the right side may be arranged so that its middle portion is bent to the left side. The second line LVP2b of the right side may include an area overlapping with the gate voltage line GVL2b of the right side.

The gate voltage line GVL2a and GVL2b may be electrically connected to the pad BPAD of the second area BPA2a and BPA2b. For example, the gate voltage line GVL2a and GVL2b may be disposed at an area between the first line HVP2 and the second line LVP2a and LVP2b. For example, the gate voltage line GVL2a and GVL2b may be disposed adjacent to the second lines LVP2a and LVP2b, with the second lines LVP2a and LVP2b interposed between the gate voltage lines GVL2a and GVL2b.

Referring to FIG. 7, the gate voltage line GVL2a of the left side may be electrically connected to the pad BPAD of the second area BPA2a of the left side. The gate voltage line GVL2b of the right side may be electrically connected to the pad BPAD of the second area BPA2b of the right side.

The gate voltage line GVL2a of the left side may be a a forme of a curved line. The gate voltage line GVL2a of the left side may be disposed so that its middle portion is bent to the left side.

The gate voltage line GVL2b of the right side may be in a form of a curved line. The gate voltage line GVL2b of the right side may be arranged so that its middle portions is bent to the right side.

The first line HVP2 may be electrically connected to the pad BPAD of the third area BPA3. The first line HVP2 may have a wide plate shape, but embodiments of the present disclosure are not limited thereto.

Referring to FIG. 7, the first line HVP2 of the left side of the portion where the first line HVP2 is connected to the pad BPAD may be electrically connected to the pad BPAD in the third area BPA3a of the left side. Among the portions where the first line HVP2 is connected to the pad BPAD, the first line HVP2 of the right side may be electrically connected to the pad BPAD in the third area BPA3b of the right side.

The first line HVP2 may be disposed closer to the data driving circuit 120 than the gate voltage lines GVL2a and GVL2b.

The first line HVP2 may have a shape in which an area where the data driving circuit 120 will be disposed is removed from the rectangular shape. Accordingly, the shape of the first line HVP2 may be a “U” shape, but embodiments of the present disclosure are not limited thereto. For example, referring to FIG. 7, the first line HVP2 may include a portion disposed below the data driving circuit 120, a portion disposed to the left side of the data driving circuit 120, and a portion disposed to the right side of the data driving circuit 120.

Referring to FIG. 7, the first line HVP2 may be coupled or connected to the pad BPAD in the third area BPA3a and BPA3b, and may be disposed to extend downward from a portion coupled to the pad BPAD. The first line HVP2 may be disposed adjacent to the left and right areas LA3 and LA4 of the data driving circuit 120 and arranged parallel to a side of the left and right areas LA3 and LA4 of the data driving circuit 120. The substrate SUB may be bent in the left and right areas LA3 and LA4.

The first line HVP2 shown in FIG. 7 may be disposed adjacent to the data driving circuit 120. For example, the first line HVP2 may be arranged to extend in a vertical direction from a portion coupled to the pad BPAD. For example, the first line HVP2 may be disposed across the entire third area BPA3a and BPA3b.

Since the first line HVP2 is arranged to extend in the vertical direction from the portion coupled to the pad BPAD, the portion of the first line HVP2 adjacent to the pad BPAD may be relatively wide. Since the portion of the first line HVP2 adjacent to the pad BPAD is relatively wide, there may be reduced the resistance of the portion of the first line HVP2 adjacent to the pad BPAD.

For example, since the first line HVP2 is arranged to extend in the vertical direction from the portion coupled to the pad BPAD, the first line HVP2 may have relative small resistance in the portion adjacent to the pad BPAD. The resistance of the first line HVP2 adjacent to the pad BPAD may be relatively small, and thus power consumption may be lowered.

The data driving circuit 120 may include a first area LA1, a second area LA2, a third area LA3, and a fourth area LA4. For example, the first to fourth areas LA1 to LA4 may be the first to fourth side areas, but are not limited to these terms.

The first area LA1 may be an area where the data driving circuit 120 is adjacent to the pad BPAD. The first area LA1 may be an upper area or a top area of the data driving circuit 120.

The second area LA2 may be an area opposite or face the first area LA1. The second area LA2 may be a lower area or a bottom area of the data driving circuit 120.

The third area LA3 and the fourth area LA4 may be areas connecting the first area LA1 and the second area LA2 or between the first area LA1 and the second area LA2. The third area LA3 and the fourth area LA4 may be left and right areas of the data driving circuit 120.

Each of the width of the first area LA1 and the width of the second area LA2 may be longer than the each of widths of the third area LA3 and the fourth area LA4.

When the bonding (or attaching) process proceeds, pressure may be applied from an upper portion to a lower portion of the data driving circuit 120. Additionally, when the bonding (or attaching) process proceeds, heat may be applied to the data driving circuit 120. As the bonding (or attaching) process proceeds for a predetermined time, the data driving circuit 120 may be coupled to the substrate SUB.

When the bonding (or attaching) process proceeds, the portion of the substrate SUB overlapping the data driving circuit 120 may be bent. Accordingly, cracks may occur in the outer area of the data driving circuit 120. This may be referred to as a crack issue. The cracks may occur in an outer area of the data driving circuit 120, and cracks may also occur in the lower part of the first planarization layer (PLN1 in FIG. 6). Additionally, cracks may also occur in a portion of the gate voltage line GVLb disposed below the first planarization layer PLN1. As cracks occur, moisture may penetrate into the inside of the substrate SUB. In addition, as cracks occur in line, there may occur the difficulty in signal transmission or voltage supply. For example, cracks may occur in the gate voltage lines GVLb, and thus the gate voltage lines GVLb may not be able to transmit signals.

Referring to FIGS. 7, 8, and 9, the data driving circuit 120 may be disposed to overlap a portion of the first line HVP2. Since a portion of the first line HVP2 is disposed to overlap the lower part of the data driving circuit 120, crack issues, which may occur during the bonding process, may be prevented. Accordingly, there may be improved the problem of signal transmission or voltage supply which may occur due to cracks. Referring to FIGS. 7, 8 and 9, there may be identified an overlap area OLA. The overlap area OLA may be an area where a portion of the first line HVP2 and a portion of the data driving circuit 120 overlap.

Referring to FIG. 7, the overlap area OLA may include a second area LA2, a third area LA3, and a fourth area LA4. Referring to FIG. 7, the first line HVP2 may be disposed to overlap the data driving circuit 120 in the second area LA2, third area LA3, and fourth area LA4. For example, the first line HVP2 may overlap both ends of the data driving circuit 120 and may overlap the data driving circuit 120 in the longitudinal direction. Since the first line HVP2 is disposed to extend in the vertical direction (or up-and-down direction) from a portion coupled to the pad BPAD, the first line HVP2 may be disposed to overlap a portion of the data driving circuit 120.

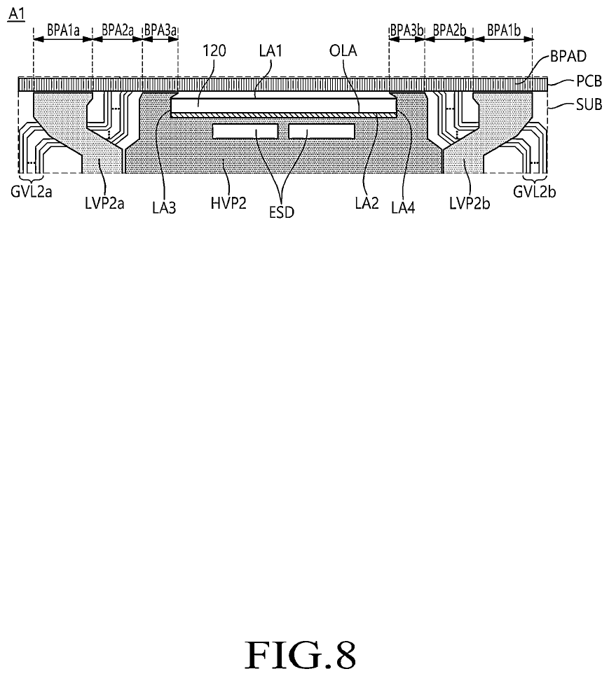

Referring to FIG. 8, the overlap area OLA may be a same as the second area LA2. Referring to FIG. 8, the first line HVP2 may be disposed to overlap the data driving circuit 120 in the second area LA2. For example, the first line HVP2 may overlap the data driving circuit 120 in the longitudinal direction. Since the first line HVP2 is disposed to extend in the vertical direction (or up-and-down direction) from a portion coupled to the pad BPAD, the first line HVP2 may be arranged adjacent to the data driving circuit 120.

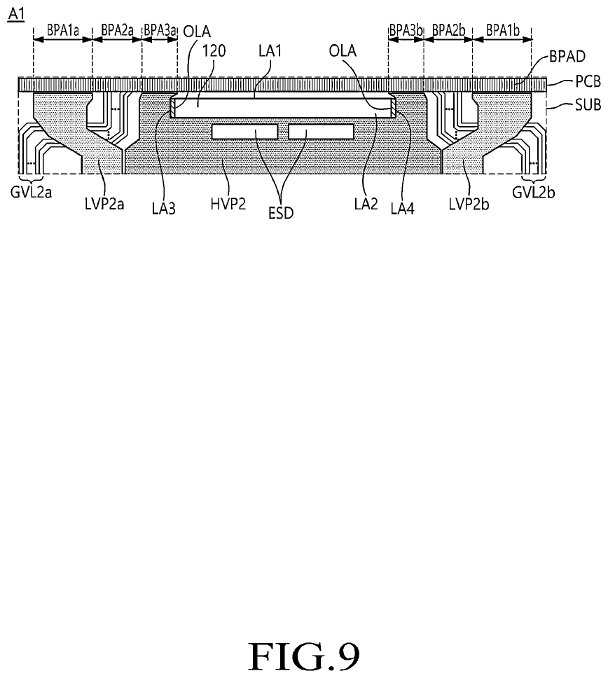

Referring to FIG. 9, the overlap area OLA may include a third area LA3 and a fourth area LA4. Referring to FIG. 9, the first line HVP2 may be disposed to overlap the data driving circuit 120 in the third area LA3 and the fourth area LA4. For example, the first line HVP2 may overlap both ends of the data driving circuit 120. Since the first line HVP2 is disposed to extend in the vertical direction (or up-and-down direction) from a portion coupled to the pad BPAD, the first line HVP2 may be disposed to overlap a portion of the data driving circuit 120.

When the bonding (or attaching) process proceeds, the substrate SUB overlapping the outer edge of the data driving circuit 120 may be bent. Accordingly, cracks may occur on the substrate SUB or inside the substrate SUB. Referring to FIGS. 7 to 9, since a portion of the first line HVP2 is disposed to overlap a portion of the data driving circuit 120 in the overlap area OLA, there may prevent a crack from occurring on the substrate SUB or inside the substrate SUB.

Referring to FIG. 7, the first line HVP2 may have a wide plate shape. An area of the first line HVP2 may be larger than an area of the gate voltage line GVL2a and GVL2b. The gate voltage line GVL2a and GVL2b may be in a form of a thin line. Since the first line HVP2 has a wide plate shape, the density of the first line HVP2 may be greater than the density of the gate voltage line GVL2a and GVL2b. And thus, there may provide an effect of dispersing a strain applied to the display panel 110.

Referring to FIG. 7, the first line HVP2, which has a wide plate shape, may be disposed adjacent to the data driving circuit 120. Since the first line HVP2 is disposed adjacent to the data driving circuit 120, there may prevent the cracks from occurring in the voltage line adjacent to the data driving circuit 120.

According to embodiments of the present disclosure, a portion of the first line HVP2 is disposed to overlap a portion of the data driving circuit 120, thereby reducing stress and/or strain applied to the display panel 110 and preventing cracks from occurring on the substrate SUB or inside the substrate SUB.

The first line HVP2 may have a wide plate shape. In the case of wide plate shapes, metal density may be higher than that of thin lines. According to embodiments of the present disclosure, the first line HVP2 has a wide plate shape with a relatively higher metal density compared to the thin line, thereby reducing the stress and/or strain applied to the display panel 110.

Referring to FIGS. 7 to 9, the first line HVP2 is disposed to extend in the vertical direction (or up-and-down direction) from the portion coupled to the pad BPAD, so that the first line HVP2 may have the relatively small resistance in a portion adjacent to the pad BPAD. The resistance of the first line adjacent to the pad BPAD may be relatively small, and thus power consumption may be lowered.

Referring to FIG. 7, an electrostatic discharge circuit ESD may be disposed on the first line HVP2. Referring to FIG. 7, two electrostatic discharge circuits ESD may be disposed on the first line HVP2. Though two electrostatic discharge circuits ESD are shown, but is not limited thereto. That is, there may be included two or more electrostatic discharge circuits, but embodiments of the present disclosure are not limited thereto.

The first line HVP1 shown in FIG. 5 may be disposed so as not to overlap the electrostatic discharge circuit ESD, and the first line HVP2 shown in FIG. 7 may be disposed to overlap with the electrostatic discharge circuit ESD.

The first line HVP2 shown in FIG. 7 may be disposed adjacent to the surrounding areas LA2, LA3 and LA4 of the data driving circuit 120. The first line HVP1 shown in FIG. 5 may be not disposed in the area between two electrostatic discharge circuits ESD, and the first line HVP2 shown in FIG. 7 may be disposed in the area between two electrostatic discharge circuits ESD. For example, an electrostatic discharge circuit ESD may connect between the first lines HVP2. The first line HVP2 shown in FIG. 7 may be disposed adjacent to the second area LA2 of the data driving circuit 120, and may be arranged to extend in a downward direction from the second area LA2.

Since the electrostatic discharge circuit ESD is disposed on the first line HVP2, the first line HVP2 may be disposed to extend in a downward direction to the second area LA2 of the data driving circuit 120, and may be arranged to pass a lower part of the electrostatic discharge circuit ESD. Referring to FIGS. 7 and 9, the first line HVP2 may be disposed to overlap the data driving circuit 120 in the second area LA2 of the data driving circuit 120, and may be disposed to overlap the electrostatic discharge circuit ESD in a lower portion of the second area LA2. Referring to FIG. 8, the first line HVP2 is disposed adjacent to the data driving circuit 120 in the second area LA2 of the data driving circuit 120, and may be disposed to overlap the electrostatic discharge circuit ESD in a lower portion of the second area LA2.

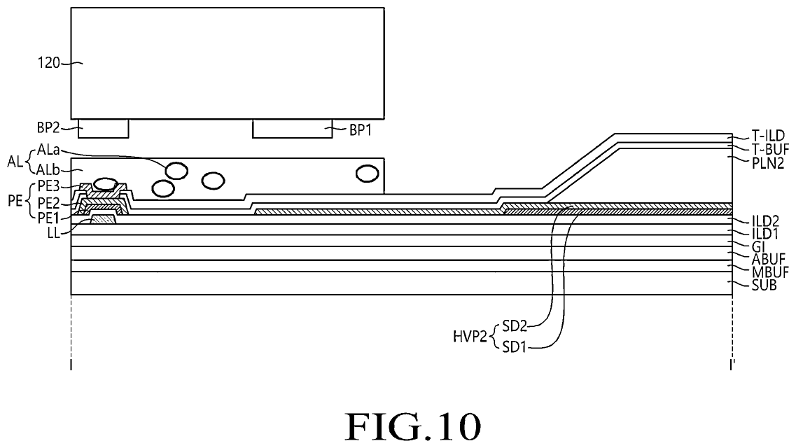

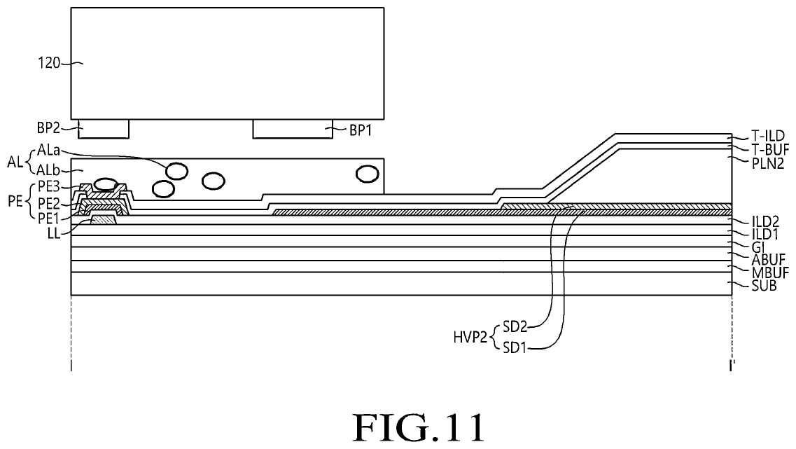

FIGS. 10 and 11 are diagrams illustrating area A1 of FIG. 4 according to embodiments of the present disclosure. FIGS. 10 and 11 are cross-sectional views illustrating the data driving circuit 120 and the substrate SUB being combined in a chip-on-film scheme.

In describing FIGS. 10 and 11, there may be omitted descriptions of configurations that are substantially the same as those shown in FIG. 6.

The first line HVP2 may include a first source-drain electrode SD1 and a second source-drain electrode SD2. The first source-drain electrode SD1 and the second source-drain electrode SD2 may be disposed below (or under) the second planarization layer PLN2.

The first source-drain electrode SD1 shown in FIGS. 10 and 11 may include a same material as the first source-drain electrode SD1 shown in FIG. 3, but embodiments of the present disclosure are not limited thereto. The first source-drain electrode SD1 shown in FIGS. 10 and 11 may be formed together with the first source-drain electrode SD1 shown in FIG. 3, but embodiments of the present disclosure are limited thereto.

The second source-drain electrode SD2 shown in FIGS. 10 and 11 may include the same material as the second source-drain electrode SD2 shown in FIG. 3, but embodiments of the present disclosure are not limited thereto. The second source-drain electrode SD2 shown in FIGS. 10 and 11 may be formed together with the second source-drain electrode SD2 shown in FIG. 3, but embodiments of the present disclosure are limited thereto.

Referring to FIG. 10, the first source-drain electrode SD1 may be disposed on the second interlayer insulating film (or third insulating film) ILD2.

The first source-drain electrode SD1 may be disposed to overlap the second planarization layer PLN2. The first source-drain electrode SD1 may be disposed closer to the data driving circuit 120 than the second planarization layer PLN2. For example, one side or the left end of the first source-drain electrode SD1 may be disposed closer to the data driving circuit 120 than the second planarization layer PLN2. For example, the first source-drain electrode SD1 may be a first metal layer, but is not limited thereto.

The second source-drain electrode SD2 may be disposed on the first source-drain electrode SD1. For example, the second source-drain electrode SD2 may be disposed to cover the first source-drain electrode SD1. The second source-drain electrode SD2 may be disposed under a portion of the data driving circuit 120. For example, the second source-drain electrode SD2 may be disposed to further extend to the data driving circuit 120 than the first source-drain electrode SD1. For example, the second source-drain electrode SD2 may overlap the adhesive layer AL and the data driving circuit 120. A portion of the second source-drain electrode SD2 may be disposed between the substrate SUB and the data driving circuit 120. For example, the second source-drain electrode SD2 may be a second metal layer, but is not limited thereto.

The second source-drain electrode SD2 may overlap the data driving circuit 120. For example, the second source-drain electrode SD2 may be disposed under the data driving circuit 120 to overlap the data driving circuit 120. Accordingly, when the bonding (or attaching) process proceeds, there may prevent the cracks from occurring in the outer area of the data driving circuit 120.

Referring to FIG. 11, the first source-drain electrode SD1 may be disposed on the second interlayer insulating film ILD2.

The second source-drain electrode SD2 may be disposed on the first source-drain electrode SD1, and may be disposed so as for a portion of the first source-drain electrode SD1 to be exposed. For example, the second source-drain electrode SD2 may be disposed to expose the left portion of the first source-drain electrode SD1.

Referring to FIG. 11, the first source-drain electrode SD1 may be disposed under a portion of the data driving circuit 120. A portion of the first source-drain electrode SD1 may be disposed between the substrate SUB and the data driving circuit 120.

For example, the first source-drain electrode SD1 may be disposed under the data driving circuit 120, overlapping with the data driving circuit 120. Accordingly, when the bonding (or attaching) process proceeds, cracks can be prevented from occurring in the outer area of the data driving circuit 120.

According to embodiments of the present disclosure, there may provide a display apparatus capable of preventing or at least reducing cracks from occurring in a display panel.

According to embodiments of the present disclosure, there may provide a display apparatus capable of preventing or at least reducing the display panel from bending during a bonding process.

According to embodiments of the present disclosure, there may provide a display apparatus capable of preventing or at least reducing the voltage line from being damaged.

According to embodiments of the present disclosure, there may provide a display apparatus capable of reducing the resistance of line to which voltage is supplied.

According to embodiments of the present disclosure, there may provide a display apparatus capable of implementing low power consumption by reducing the resistance.

A display apparatus according to various embodiments of the present disclosure may be applied to a mobile apparatus, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book apparatus, a portable multimedia player (PMP), a personal digital assistant (PDA), a MP3 player, a mobile medical apparatus, a desktop PC, a laptop PC, a netbook computer, a workstation, a navigation, a vehicle navigation, a vehicle display apparatus, a vehicle apparatus, a theater apparatus, a theater display apparatus, a television, a wallpaper apparatus, a signage apparatus, a game apparatus, a laptop, a monitor, a camera, a camcorder, and a home appliances, etc.

Embodiments of the present disclosure described above are briefly described as follows.

A display apparatus according to embodiments of the present disclosure may include a substrate, a pad electrode on the substrate, a first line on the substrate, the first line including a first metal layer and a second metal layer, an adhesive layer on the pad electrode, and a data driving circuit that is adjacent to the first line.

According to embodiments of the present disclosure, the data driving circuit may overlap a portion of the first line.

According to embodiments of the present disclosure, the substrate may further include a pad coupled to a printed circuit board. The pad may include a first area at an outermost portion of the pad, a second area that is adjacent to the first area, and a third area electrically connected to the first line.

According to embodiments of the present disclosure, the display apparatus may further include a second line electrically connected to the pad in the first area, and a gate voltage line electrically connected to the pad in the second area.

According to embodiments of the present disclosure, the first line may be closer to the data driving circuit than the gate voltage line.

According to embodiments of the present disclosure, an area of the first line may be larger than an area of the gate voltage line.

According to embodiments of the present disclosure, a density of the first line may be greater than a density of the gate voltage line.

According to embodiments of the present disclosure, the first metal layer may be on the substrate. The second metal layer may overlap a portion of the data driving circuit.

According to embodiments of the present disclosure, the second metal layer may be on the first metal layer.

According to embodiments of the present disclosure, the first metal layer may overlap a portion of the data driving circuit. The second metal layer may be on the first metal layer.

According to embodiments of the present disclosure, the data driving circuit may include a first bump overlapping the first line, and a second bump electrically connected to the pad electrode.

According to embodiments of the present disclosure, the second bump may be at an outside of the first bump.

According to embodiments of the present disclosure, the data driving circuit may include a first area adjacent to the pad, a second area facing the first area, and a third area between the first area and the second area.

According to embodiments of the present disclosure, the first line may overlap the data driving circuit in the second area and the third area.

According to embodiments of the present disclosure, the first line may overlap the data driving circuit in the second area.

According to embodiments of the present disclosure, the first line may overlap the data driving circuit in the third area.

According to embodiments of the present disclosure, the first line may be adjacent to the third area, and may be parallel to a side of the third area.

According to embodiments of the present disclosure, the substrate may be bent in the third area.

According to embodiments of the present disclosure, the adhesive layer may include an adhesive and a conductive ball in the adhesive.

According to embodiments of the present disclosure, the display apparatus may further include a controller configured to control the data driving circuit. The controller may be on the printed circuit board, and the data driving circuit may be on the substrate.

According to embodiments of the present disclosure, the display apparatus may further include an electrostatic discharge circuit connecting between first lines including the first line.

According to embodiments of the present disclosure, the gate voltage line may be between the first line and the data driving circuit.

According to embodiments of the present disclosure, the gate voltage line at a left side may be arranged to extend downward from the pad, and then bent to the left side. The gate voltage line at a right side may be arranged to extend downward from the pad, and then bent to the right side. The second line at the left side may be at the right side of the gate voltage lines disposed at the left side. The second line at the right side may be at the left side of the gate voltage line at the right side.

According to embodiments of the present disclosure, the adhesive layer may include an adhesive and a conductive ball in the adhesive. The conductive ball may be between the second bump and the pad electrode.

According to embodiments of the present disclosure, the gate voltage line may be adjacent to the second line, with the second line interposed between the gate voltage line.

According to embodiments of the present disclosure, each of a width of the first area of the data driving circuit and a width of the second area of the data driving circuit may be longer than a width of the third area of the data driving circuit.

According to embodiments of the present disclosure, the display apparatus may further include an electrostatic discharge circuit between a lower part of the first line and the data driving circuit.

According to embodiments of the present disclosure, the first line may have a “U” shape.

According to embodiments of the present disclosure, the first line may be arranged to extend in a vertical direction from a portion coupled to the pad.

According to embodiments of the present disclosure, the first line may be disposed across the entire third area.

It will be apparent to those skilled in the art that various modifications and variations may be made in the apparatus of the present disclosure without departing from the scope of the disclosure. Thus, it is intended that the present disclosure covers the modifications and variations of this disclosure that come within the scope of the claims and their equivalents.

What is claimed is:

1. A display apparatus, comprising:
a substrate;
a pad electrode on the substrate;
a first line on the substrate, the first line including a first metal layer and a second metal layer;
an adhesive layer on the pad electrode; and
a data driving circuit that is adjacent to the first line.

2. The display apparatus of claim 1, wherein the data driving circuit overlaps a portion of the first line.

3. The display apparatus of claim 1, wherein the substrate further comprises:
a pad coupled to a printed circuit board, the pad including:
a first area at an outermost portion of the pad;
a second area that is adjacent to the first area; and
a third area electrically connected to the first line.

4. The display apparatus of claim 3, further comprising:
a second line electrically connected to the pad in the first area; and
a gate voltage line electrically connected to the pad in the second area.

5. The display apparatus of claim 4, wherein the first line is closer to the data driving circuit than the gate voltage line.

6. The display apparatus of claim 4, wherein an area of the first line is larger than an area of the gate voltage line.

7. The display apparatus of claim 4, wherein a density of the first line is greater than a density of the gate voltage line.

8. The display apparatus of claim 1, wherein the first metal layer is on the substrate, and the second metal layer overlaps a portion of the data driving circuit.

9. The display apparatus of claim 8, wherein the second metal layer is on the first metal layer.

10. The display apparatus of claim 1, wherein the first metal layer overlaps a portion of the data driving circuit, and the second metal layer is on the first metal layer.

11. The display apparatus of claim 1, wherein the data driving circuit includes a first bump overlapping the first line, and a second bump electrically connected to the pad electrode.

12. The display apparatus of claim 11, wherein the second bump is at an outside of the first bump.

13. The display apparatus of claim 3, wherein the data driving circuit includes:
a first area adjacent to the pad;
a second area facing the first area; and
a third area between the first area and the second area.

14. The display apparatus of claim 13, wherein the first line overlaps the data driving circuit in the second area and the third area.

15. The display apparatus of claim 13, wherein the first line overlaps the data driving circuit in the second area.

16. The display apparatus of claim 13, wherein the first line overlaps the data driving circuit in the third area.

17. The display apparatus of claim 13, wherein the first line is adjacent to the third area and is parallel to a side of the third area.

18. The display apparatus of claim 13, wherein the substrate is bent in the third area.

19. The display apparatus of claim 1, wherein the adhesive layer includes an adhesive and a conductive ball in the adhesive.

20. The display apparatus of claim 3, further comprising:
a controller configured to control the data driving circuit,
wherein the controller is on the printed circuit board, and the data driving circuit is on the substrate.

21. The display apparatus of claim 1, further comprising:
an electrostatic discharge circuit connecting between first lines including the first line.
